(19) United States
(12) Patent Application Publication
(10) Pub. No.: US 2009/0102559 A1
(43) Pub. Date: Apr. 23, 2009

(54) MONOTONIC VARIABLE GAIN AMPLIFIER AND AN AUTOMATIC GAIN CONTROL CIRCUIT

(75) Inventors: Jan Van Sinderen, Liempde (NL); Sebastian Prouet, Caen (FR)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/094,306

(22) PCT Filed: Nov. 22, 2006
(86) PCT No.: PCT/IB06/54387

§ 371 Date: Aug. 27, 2008

(30) Foreign Application Priority Data
Nov. 23, 2005 (EP) 05300961.9
Nov. 22, 2006 (IB) PCT/IB2006/054387

(51) Int. Cl. H03G 3/30; H03F 3/45

(52) U.S. Cl. 330/254; 330/285

(57) ABSTRACT

A monotonic variable gain amplifier which can be controlled to achieve a desired gain. The amplifier has: —at least two amplifier stages (41-45) connected in parallel between input and output terminals, each amplifier stage including: * a fixed gain transconductance amplifier (100, 102) through which a bias current (Ibᵢ) flows controlled by the input signal,—a controllable current divider (104, 106) controllable to vary the ratio of the amount of the bias current (Ibᵢ) that is drawn from a first output point to the amount (l₁ᵢ) of the bias current that is drawn from a voltage source, and—a control loop (190) to keep a DC voltage combined with an outputted amplified DC current at a constant level.

### FIELD OF THE INVENTION

The present invention relates to a monotonic variable gain amplifier and an automatic gain control circuit as well as a method of operating them.

### BACKGROUND OF THE INVENTION

Monotonic variable gain amplifiers have a gain that can be continuously and monotonically varied between a lower limit Gₘᵢₙ and an upper limit Gₘₐₓ under the control of an external electronic device that outputs a control voltage.

The term “monotonic” means that the gain continuously grows between [Gₘᵢₙ; Gₘₐₓ] as the control continuously increases or, alternatively, continuously decreases.

The term “continuous” means that there is no step or discontinuity in the gain variation between [Gₘᵢₙ; Gₘₐₓ].

The gain of the monotonic variable gain amplifier is defined as the amplitude ratio of a periodic output current I_{OUT} to a periodic input voltage V_{IN} or current I_{IN}.

Existing monotonic variable gain amplifiers have:
at least one input terminal to receive a periodic electrical input signal to be amplified,
at least one output terminal to output a periodic current with an amplified amplitude, combined with a DC voltage.

Some monotonic variable gain amplifiers use transconductance amplifiers (refer to US 2002/0086651, to Prentice et al. for example). Preferably, these monotonic variable gain amplifiers should use fixed gain transconductance amplifiers rather than variable gain transconductance amplifiers because the variable gain transconductance amplifiers are more noisy and less linear.

However, the fixed gain transconductance amplifiers become noisy when a high bias current flows through them.

### SUMMARY OF THE INVENTION

Accordingly, it is an object of the invention to provide a monotonic variable gain amplifier which is less noisy.

With the foregoing and other objects in view there is provided in accordance with the invention a monotonic variable gain amplifier comprising:
at least two amplifier stages connected in parallel between the input and output terminals, each amplifier stage including:
   a fixed gain transconductance amplifier having at least one input point to receive the input signal, and a periodic current output through which a bias current flows controlled by the input signal,
   a controllable current divider having a first and a second output point connected to the output terminal and to a voltage source respectively, and an input point connected to the fixed gain transconductance amplifier periodic current output, the current divider being controllable to vary the ratio of the amount of the bias current which is drawn from the first output point to the amount of the bias current which is drawn from the second output point, and
a control loop to keep the DC voltage combined with the outputted amplified periodic current at a constant level.

In the above monotonic variable gain amplifier, the DC bias current that flows through each of the fixed gain transconductance amplifiers is smaller than if only one amplifier stage were used for obtaining the same gain. A smaller bias current causes less noise from the current dividers to occur. Therefore, the overall noise of the monotonic variable gain amplifier is reduced.

The following embodiments of the above monotonic variable gain amplifier may comprise one or several of the following features:
at least one of the amplifier stages includes a controllable switch that can be switched from a conductive state in which the bias current can flow through the fixed gain transconductance amplifier to a non-conductive state in which the bias current cannot flows through the fixed gain transconductance amplifier, and
the monotonic variable gain amplifier comprises a control unit to automatically switch the controllable switch to the non-conductive state if the desired gain can be achieved using only the other amplifier stages with a bias current in each of the other stages lower than a predetermined threshold;
the fixed gain transconductance amplifier has a feedback loop to keep its gain constant;
the fixed gain values of the transconductance amplifiers are chosen so as to form a geometric progression having a common ratio greater than two;
the monotonic variable gain amplifier has two input terminals to receive a differential periodic electrical input signal and two output terminals to output a differential amplified periodic signal, and the product of the bandwidth at −3 dB of the control loop by the DC gain of the current control loop is greater than 3.f₀, where f₀ is the frequency of the differential input signal;
the current divider comprises a left transistor having a collector connected to the first output point and an emitter connected to the input point through a resistor, and a right transistor having a collector connected to the voltage source and an emitter connected to the input point through another resistor of equal value.

The above embodiments of the monotonic variable gain amplifier present the following advantages:
switching off the bias current of an amplifier stage if this one is not necessary to achieve the desired gain, reduces the current consumption of the monotonic variable gain amplifier,
using fixed gain transconductance amplifiers with a feedback loop increases the linearity of the monotonic variable gain amplifier,
using transconductance amplifiers having fixed gain that form a geometric progression having a common ratio greater than two reduces the number of stages needed to achieve a desired gain,
having a bandwidth-gain product in the control loop greater than three times the frequency f₀ of the input signal improves the common mode rejection by at least 10 dB,
a current divider with resistive degeneration decreases the modulation of the output signal amplitude by noise from the control signal applied to this current divider.

The invention also relates to an automatic gain control circuit comprising:
a monotonic variable gain amplifier having at least one input terminal to receive a periodic electrical signal and at least one output terminal to output an amplified periodic current, the monotonic variable gain amplifier being as described above, and
a detector to tune the gain of the monotonic variable gain amplifier so as to maintain the amplitude of the amplified periodic current constant even if the amplitude of the periodic electrical input signal varies.

The invention also relates to a method of controlling the above monotonic variable gain amplifier wherein the switching of the controllable switch is automatically triggered as a function of the desired gain to be achieved.

The embodiments of the method of controlling the monotonic variable gain amplifier may comprise one or several of the following features:
the step of switching the controllable switch of an amplifier stage to the conductive state at a time when the corresponding current divider is controlled not to draw any amount of the bias current of this stage from its first output point, and
the step of automatically switching the controllable switch of an amplifier stage to the conductive state when the amount of the bias current in another amplifier stage drawn from the first output point of this other amplifier stage reaches a predetermined percentage of the bias current, the predetermined percentage being at least higher than 80%.

The above embodiments of the control method present the following advantages:
switching the controllable switch of an amplifier stage to the conductive state before the stage starts to draw a substantial amount of the bias current from its first output point limits the amplitude of a voltage peak in the DC voltage outputted with the amplified periodic current due to the switching of the controllable switch, and
automatically switching to the conductive state when the bias current drawn from the first output point in another amplifier stage represents at least 80% of the bias current of this other stage, allows to start the amplifier stage without causing a peak in the DC voltage and also limits the power consumption of the monotonic variable gain amplifier because the amplifier stage is not started too early before it becomes useful.

These and other aspects of the invention will be apparent from the following description, drawings and claims.

### BRIEF DESCRIPTION OF THE DRAWINGS

FIG. 1 is a schematic diagram of a television tuner having an automatic gain control circuit,

FIG. 2 is a schematic diagram of a monotonic variable gain amplifier used in the automatic gain control circuit of FIG. 1,

FIG. 3 is a flowchart of a method for controlling the monotonic variable gain amplifier of FIG. 2,

FIG. 4 is a graph of the intensity of currents I₀ᵢ flowing through amplifier stages of the amplifier of FIG. 2 according to a control voltage V_{CTRL},

FIG. 5 is a graph of the intensity of currents Ibᵢ flowing through amplifier stages of the amplifier of FIG. 2 according to control voltage V_{CTRL},

FIG. 6 is a schematic diagram of another embodiment of a current divider to be used in the amplifier of FIG. 2, and

FIG. 7 is a schematic diagram of an embodiment of a fixed gain transconductance amplifier with a feedback loop that can be used in the amplifier of FIG. 2.

### DETAILED DESCRIPTION

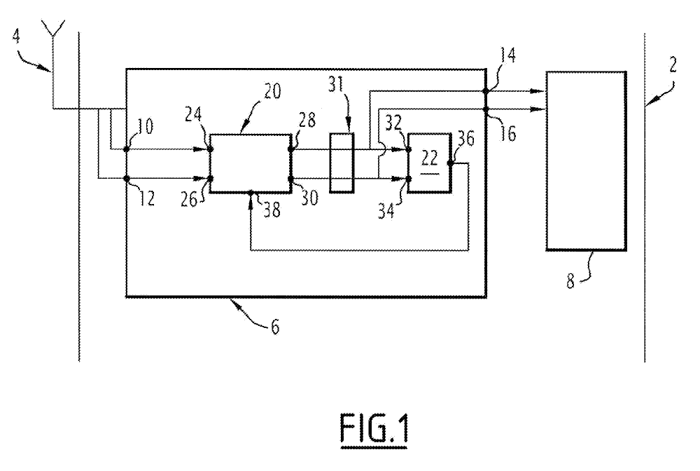

FIG. 1 shows a television tuner 2 connected to an antenna 4 to receive wireless signals, for example.

In the following description functions or constructions well-known to a person of ordinary skill in the art are not described in detail.

Tuner 2 has an AGC (Automatic Gain Control) circuit 6 connected to a digital signal processor 8.

For example, circuit 6 has input terminals 10 and 12 to receive a differential voltage V_{INP}, V_{INN} and two output terminals 14, 16 to output a differential voltage signal V_{OUTP}, V_{OUTN}.

Voltages V_{INP}, V_{INN}, V_{OUTP}, and V_{OUTN} are periodic voltages and preferably alternating current or AC voltages.

The gain of circuit 6 is automatically adjusted to keep the amplitude of output voltages V_{OUTP} and V_{OUTN} at a constant level regardless of the amplitudes of the received voltage V_{INP} and V_{INN}.

Circuit 6 has a monotonic variable gain amplifier 20 and a detector 22 to tune amplifier 20.

More precisely, amplifier 20 has two input terminals 24, 26 directly connected to terminals 10 and 12, respectively. Amplifier 20 also has two output terminals 28, 30 directly connected to output terminals 14 and 16, respectively, through a current-to-voltage transformer stage 31.

Output terminals 28 and 30 are also connected to input terminals 32 and 34 of detector 20, respectively through transformer stage 31. Detector 22 has an output terminal 36 connected to an input control terminal 38 of amplifier 20. Terminal 38 receives a control voltage V_{CTRL}.

Amplifier 20 is designed to amplify voltages V_{INP}, V_{INN} and to output the amplified periodic current I_{OUTP} and I_{OUTN} through terminals 28 and 30 combined with a DC voltage V_{O}, respectively. Typically, currents I_{OUTP} and I_{OUTN} are alternating or AC currents. The gain of amplifier 20 is tuned according to voltage V_{CTRL} received on terminal 38.

Detector 22 is designed to compare the power of voltages V_{OUTP}, V_{OUTN} to a fixed reference power. According to the result of this comparison, detector 22 increases or decreases voltage V_{CTRL} so as to keep the amplitude of voltages V_{OUTP} and V_{OUTN} that directly depend on the amplitudes of currents I_{OUTP} and I_{OUTN} at a constant level.

The signal processing carried out by processor 8 is beyond the scope of the present description and will not be described.

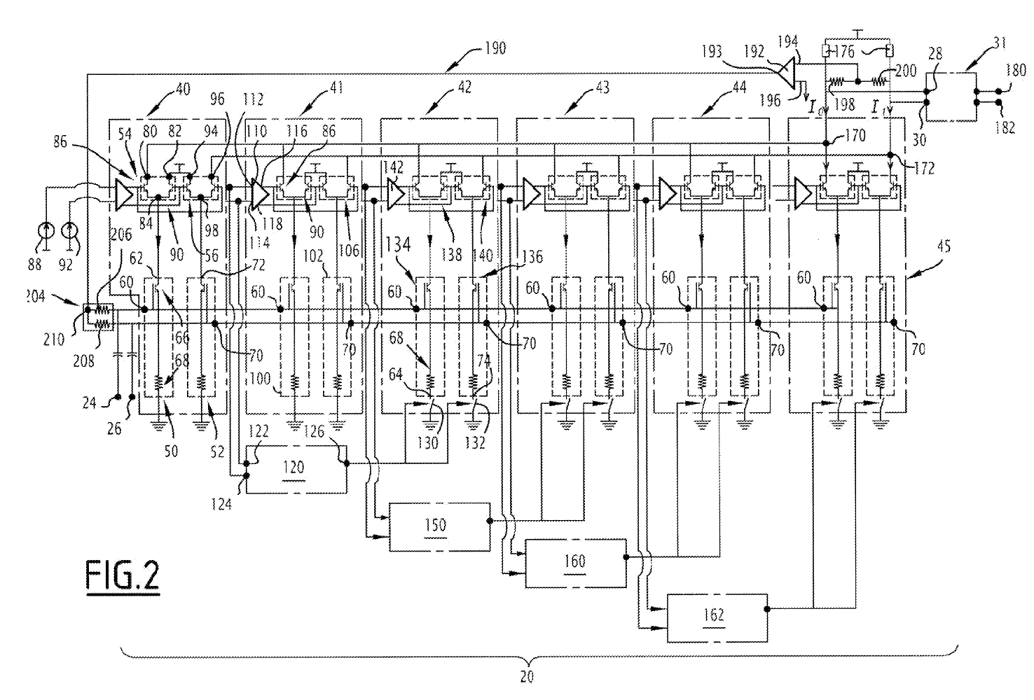

FIG. 2 shows an embodiment of amplifier 20.

Elements of amplifier 20 already described in FIG. 1 have the same reference numerals.

Amplifier 20 has at least two amplifier stages connected in parallel between, on the one hand, terminals 24, 26 and, on the other hand, terminals 28 and 30. For example, in FIG. 2, amplifier 20 has six amplifier stages 40 to 45 from left to right. Stage 40 is a fixed gain amplifier stage whereas stages 41-45 are variable gain amplifier stages.

In FIG. 2, the circuit that processes voltage V_{INN} to obtain voltage V_{OUTN} can be deduced from the circuit that processes voltage V_{INP} to obtain voltage V_{OUTP}. Thus, hereinafter only the circuit relating to voltages V_{INP} and V_{OUTP} is described in detail.

Stage 40 includes:
one differential transconductance amplifier having two fixed gain transconductance amplifiers 50, 52, and
one differential current divider having two controllable current dividers 54, 56.

The term “fixed gain” means that the gain is constant and is not controllable.

Amplifier 50 has:
an input point 60 directly connected to terminal 24, and
a periodic current output 62 through which a DC bias current Ib₁ flows which is proportional to voltage V_{INP} received on point 60.

Amplifier 50 includes a transistor 66, the collector of which is connected to output 62 and the emitter of which is connected to ground through a resistor 68. “R” is the value of resistor 68.

The gate of transistor 66 is directly connected to point 60.

Amplifier 50 has a fixed gain roughly equal to 1/R.

Amplifier 52 has:
an input point 70 directly connected to terminal 26, and
a periodic current output 72.

Amplifier 52 is identical to amplifier 50. Together they act as a differential amplifier.

Divider 54 has two AC current output points 80 and 82 and one AC current input point 84.

Point 80 is connected to output terminal 28 and receives a DC current I₀₁.

Point 82 is connected to a voltage source V_{dd} to draw a DC current I₁₁ from the voltage source.

Point 84 is connected to output 62.

Divider 54 includes a left transistor 86 having its collector directly connected to point 80 and its emitter directly connected to point 84. The base of transistor 86 is connected to a constant voltage source 88.

Divider 54 has also a right transistor 90 having its collector directly connected to point 82 and its emitter directly connected to point 84. The base of transistor 90 is connected to a constant voltage source 92.

Divider 54 together with the divider 56 forms a differential current divider.

Sources 88 and 92 output constant voltages V₁ and V₂, respectively. The values of voltages V₁ and V₂ determine the ratio of DC current I₀₁ to DC current I₁₁, and set the lower gain limit Gₘᵢₙ of amplifier 20. For example, voltage V₁ is equal to 1.8 V and voltage V₂ is equal to 1.4 V.

Current divider 56 has two AC current output points 94 and 96 and one AC input point 98. Point 94 is directly connected to source V_{dd} and point 96 is connected to output terminal 30.

Point 98 is directly connected to output 72.

Divider 56 is identical to divider 54, for example. More precisely, the bases of the transistors of divider 56 are connected to sources 88 and 92 in a similar way as for divider 54.

Stage 41 has also two fixed gain transconductance amplifiers 100 and 102, which constitute a differential fixed gain transconductance amplifier, and two current dividers 104, 106, which constitute a differential current divider and are connected between terminals 24, 26, 28 and 30, source V_{dd} and ground as disclosed in view of stage 40.

For example, amplifiers 100 and 102 are identical to amplifiers 50 and 52 and have the same fixed gain 1/R.

Current dividers 104 and 106 are also identical to current dividers 54 and 56 of stage 40. A DC current I₀₂ flows through the left transistor and a DC current I₁₂ flows through the right transistor. A DC bias current Ib₂ flows through amplifier 100.

Stage 41 has a current divider controller 110 that replaces constant voltage sources 88 and 92 of stage 40 to control the gain.

More precisely, controller 110 has two inputs 112 and 114 connected to terminal 38 and to a reference potential V_{REF2}. For example, potential V_{REF2} is equal to 0.6 V.

Input 11 2 receives voltage V_{CTRL}.

Potential V_{REF2} and voltage V_{CTRL} determine the ratio of DC current I₀₂ to DC current I₁₂. For example, current I₀₂ equal current I₁₂ when voltage V_{CTRL} equals voltage V_{REF2}.

Controller 110 has also two differential outputs 116 and 118 that vary in opposite direction with the same slope. The slope is always smaller than 50 dB/V and, preferably, ranges between 20 dB/V and 30 dB/V to lower the sensitivity of amplifier 20 to noise present in voltage V_{CTRL}. The decibel level is computed using the following relation : x dB=20 Log (V_{OUTP}/V_{INP}), where x is the number of decibels.

Outputs 116, 118 are proportional to the difference between voltage V_{CTRL} and potential V_{REF2}.

Outputs 116, 118 are directly connected to the bases of left and right transistors of divider 104, respectively.

Stage 41 is associated with a control unit 120 able to start and stop the following stage, i.e. stage 42.

Unit 120 has two inputs 122 and 124 to receive voltage V_{CTRL} and potential V_{REF2} respectively. Unit 120 has also one output 126 to output a control signal able to start and stop stage 42.

Unit 120 is designed to automatically output a control signal able to start stage 42 when current I₀₂ becomes greater than a predetermined percentage P of the bias current Ib₂ and to stop stage 42 when current I₀₂ becomes smaller than the percentage P of the bias current Ib₂. Percentage P is chosen to be greater than 80% so that stage 42 is started just before to become useful to reach the desired gain set by voltage V_{CTRL}. Similarly, percentage P is chosen to be greater than 80% so as to stop stage 42 rapidly after the instant when stage 42 becomes useless to reach the desired gain set by voltage V_{CTRL}.

For example, percentage P is chosen to be equal to or greater than 90%.

Percentage P is strictly less than 100% to avoid a peak in DC voltage V₀ when starting or stopping stage 42.

Unit 120 determines the value of I₀₂ with respect to current Ib₂ from voltage V_{CTRL} and potential V_{REF2}.

Stage 42 has a structure identical to the one of stage 41 except that it has two additional controllable switches 130 and 132 used to start and stop stage 42.

The fixed gain transconductance amplifiers, the current dividers and the controller of stage 42 are referenced as 134, 136, 138, 140 and 142 respectively.

The value of the resistors of transconductance amplifiers 134 and 136 is equal to R/2 to obtain a fixed gain equal to 2/R.

An input of controller 142 is connected to reference potential V_{REF3}. Potential V_{REF3} is equal to 0.9 Volt, for example.

Current I₀₃, I₁₃, Ib₃ in stage 42 corresponds to currents I₀₂, I₁₂ and Ib₂ of stage 41.

Switches 130 and 132 are connected between ground and AC current input of amplifiers 134 and 136, respectively.

Switches 130 and 132 are switchable between a non-conductive state in which stage 42 is stopped and a conductive state in which stage 42 is started under the control of unit 120.

Stage 42 is associated with a control unit 150 able to start and stop the following stage, i.e. stage 43, according to voltages V_{CTRL} and V_{REF3}. Unit 150 is similar to unit 120.

The structure of following stages 43, 44 and 45 is identical to the structure of stage 42.

The value of the resistors of the fixed gain transconductance amplifiers of stages 43 to 45 are equal to R/4, R/8 and R/16, respectively.

The controllers of stages 43-45 are connected to reference potential V_{REF4}, V_{REF5} and V_{REF6}, respectively. For example, potential V_{REF4}, V_{REF5} and V_{REF6} are equal to 1.2 V, 1.5 V and 1.8 V, respectively.

Current I₀₄, I₀₅, I₀₆, I₁₄, I₁₅, I₁₆, Ib₄, Ib₅ and Ib₆ of stages 43 to 45 correspond to current I₀₃, I₁₃ and Ib₃ of stage 42.

Stages 43 and 44 are associated with control units 160 and 162 to start and stop stage 44 and stage 45, respectively. Units 160 and 162 have a structure identical to unit 120 and will not be described in detail.

Points 80 of each stage 40-45 are connected to a common point 170. Similarly, points 96 of each stage 40-45 is connected to a common point 172.

Points 170 and 172 are connected to current sources 174 and 176, respectively.

DC currents that flow through points 170 and 172 are referenced as current I₀ and I₁, respectively.

Points 170 and 172 are also connected to amplified AC current output terminals 28 and 30. Terminals 28, 30 output AC currents I_{OUTP} and I_{OUTN} that reflect a variation of voltages V_{INP} and V_{INN}, respectively, but with a magnified amplitude according to V_{CTRL}. The DC voltages of terminals 28, 30 are equal to voltages V₀ and V₁, respectively.

Terminals 28 and 30 are connected to terminals 180 and 182, respectively through current-to-voltage transformer stage 31.

Transformer stage 31 is designed to transform the outputted currents I_{OUTP}, I_{OUTN}, into outputted voltages V_{OUTP}, V_{OUTN}, respectively. This circuit will not be described in further detail. For illustration, the fixed gain of the current-to-voltage transformer is equal to R.

Amplifier 20 also has a DC current control loop 190 to keep DC currents I₀ and I₁ at a constant level. This also keeps DC voltages V₀ and V₁ constant. Thus, terminals 28, 30 are adequately biased.

An integrated linear amplifier 192 has an output 193 connected to loop 190, and two inputs 194 and 196. Output 193 outputs a voltage V_{SOUT}.

Input 194 is connected to points 170 and 172 through two identical resistors 198 and 200. Input 194 receives a common mode voltage V_{SIN}.

Input 196 is connected to a reference potential V_{SREF}. Potential V_{SREF} fixes the value of voltages V₀ and V₁.

Voltage V_{SOUT} is proportional to the difference between V_{SIN} and V_{SREF}.

At its other end, loop 190 is connected to a bias unit 204.

Bias unit 204 has two resistors 206 and 208 connected in series through a middle point 210.

One end of resistor 206 is connected to input point 60 of each stage 40-45.

An end of resistor 208 is connected to input point 70 of each stage 40-45.

Common point 210 is connected to the end of loop 190.

Unit 204 is useful to bias transistor 66 of each fixed gain transconductance amplifier.

Loop 190 is designed to have a gain-band product that is greater than 3f₀ and preferably greater than 10f₀, where f₀ is the frequency of input voltage V_{INP} and V_{INN}. The product gain-band is defined as the product of the bandwidth at −3 dB of loop 190 by the DC gain of this loop. A gain-band product which is equal to 3f₀ increases the common mode rejection by 10 dB and a gain-band product which is greater than 10f₀ increases the common mode rejection by 20 dB.

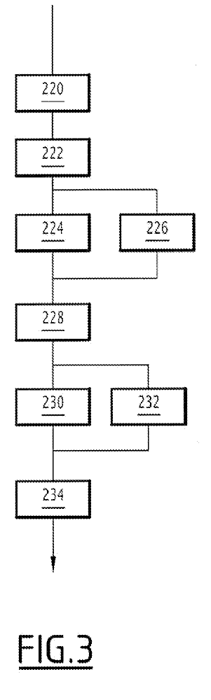

The operation of amplifier 20 will now be described with reference to FIGS. 3 to 5.

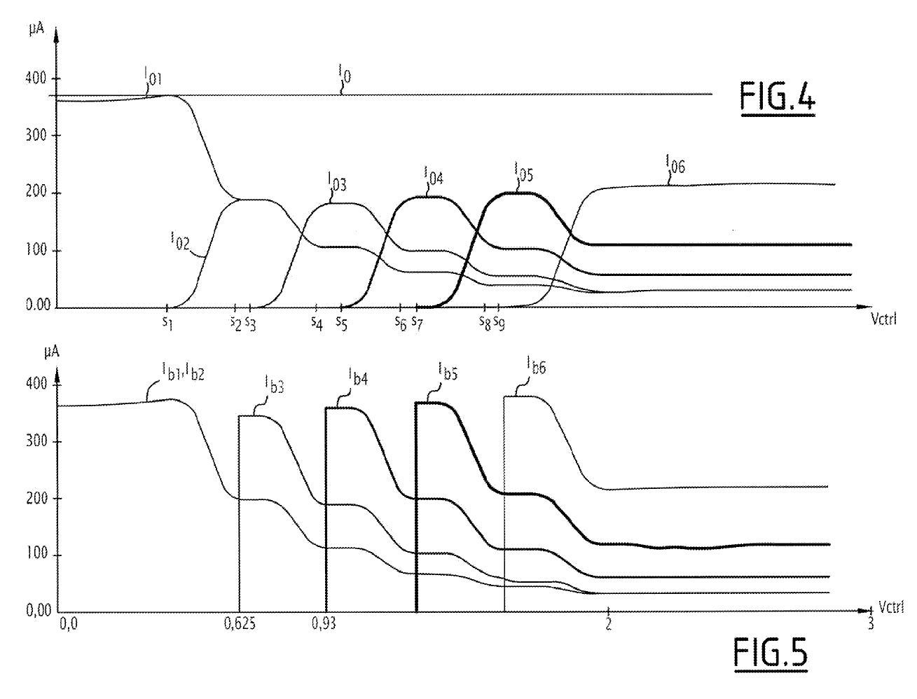

FIG. 4 represents an example of variations of currents I₀₁, I₀₂, I₀₃, I₀₄, I₀₅ and I₀₆ according to the value of voltage V_{CTRL}.

FIG. 5 shows the variation of bias currents Ib₁, Ib₂, Ib₃, Ib₄, Ib₅ and Ib₆ according to the value of voltage V_{CTRL}.

Hereinafter, the operation of amplifier 20 will only be described with respect to voltages V_{INP} and V_{OUTP}. The operation of amplifier 20 with respect to voltages V_{INN} and V_{OUTN} can be deduced from the explanation given for voltages V_{INP}, V_{OUTP}.

Firstly, it should be understood that DC currents I₀ and I₁ remain constant during the whole operation of amplifier 20. For example, if current I₀ decreases, voltage V_{SIN} will decrease. As a result, V_{SOUT} will increase the bias current in each of the stages that are started. Increasing the bias current Ibᵢ causes the currents I₀ᵢ to increase, so that finally current I₀ increases.

The value of DC current I₀ is set by the value of the current outputted by current source 174.

Here, we assume that the value of DC current I₀ is set to approximately 360 μA. We also assume that initially voltage V_{CTRL} is equal to zero.

Upon power on of amplifier 20, in step 220 (FIG. 3), stages 42 to 45 are stopped. This means that switches 130 and 132 of each stage 42 to 45 are in their non-conductive state.

Subsequently, in step 222 (FIG. 3), controller 110 of stage 41 controls current divider 104, so that current I₀₂ is zero because voltage V_{CTRL} is very small with respect to potential V_{REF2}. Thus, in these conditions, currents I₀₁, I₁₂ are equal to currents I₀ and Ib₂, respectively. Furthermore, currents Ib₁ and Ib₂ are equal because the values of resistors 68 of amplifiers 50 and 100 are equal.

In this step, the gain of amplifier 20 is equal to the lower limit Gₘᵢₙ. Here Gₘᵢₙ is equal to one.

This situation is represented in FIG. 4 before threshold S, and in FIG. 5 for voltage V_{CTRL} which is equal to zero.

We now assume that voltage V_{CTRL} is continuously increased.

Thus, in step 224 (FIG. 3), controller 110 controls divider 104 so that current I₀₂ increases with a given gradient and current I₁₂ decreases with a gradient that is opposite to the one of current I₂. As a result, current I₀₁ decreases because currents I₀₁ and I₀₂ are related to each other through the following relation:

I₀₁+I₀₂=I₀ (1)

Currents Ib₁ and Ib₂ also decrease because current I₀₁ decreases.

This is shown in FIG. 4 between thresholds S₁ and S₂ and also in FIG. 5 for voltage V_{CTRL} less than 0.625 Volt.

In parallel, in step 226 (FIG. 3), controller 142 of stage 42 controls current divider 138 so that the left transistor 86 is non-conducting.

Near threshold S2 the gain of amplifier 20 is equal to two.

When threshold S2 is exceeded, voltage V_{CTRL} is big enough for the current I₀₂ to become equal to P% of current Ib₂.

As a result, in step 228 (FIG. 3), control unit 120 starts stage 42. In step 228, unit 120 controls switches 130 and 132 of stage 42 to switch them to their conductive state. At this time, current Ib₃, which was previously zero, steps to a value close to 350 μA as shown in FIG. 5. At the beginning, current Ib₃ is entirely drawn from voltage source V_{dd} so that current Ib₃ is equal to current I₁₃. Current I₀₃ is zero. Therefore, the step in the value of current Ib₃ has no impact on current I₀. More precisely, starting stage 42 does not create any DC intensity peak in current I₀ or amplitude voltage peak in voltage V₀.

Thereafter, when voltage V_{CTRL} exceeds threshold S₃, in step 230 (FIG. 3), controller 142 controls the left transistor of divider 138, so that current I₀₃ starts to increase. As a result, currents I₀₁, and I₀₂ decrease as shown in FIG. 4. This causes bias currents Ib₁, Ib₂ and Ib₃ to decrease as shown in FIG. 5.

In parallel, in step 232 (FIG. 3), the controller of stage 43 controls transistor 86 of the current divider, so that current I₀₄ is zero because voltage V_{CTRL} is very small with respect to potential V_{REF4}.

When threshold S₄ is exceeded, current I₀₃ becomes equal to P% of current Ib₃. Thus, in step 234 (FIG. 3), control unit 150 starts the next stage, i.e. stage 43.

In a similar way, the next stages 44 and 45 are successively started as the value of voltage V_{CTRL} grows bigger.

More precisely, when voltage V_{CTRL} exceeds:
threshold S₅, current I₀₄ starts to flow through the current divider of stage 43,
threshold S₆, stage 44 is started,
threshold S₇, current I₀₅ starts to flow through the current divider of stage 44,
threshold S₈, stage 45 is started, and
threshold S₉, current I₀₆ starts to flow through the current divider of stage 45.

In FIG. 4, a line I₀ parallel to the abscissa, shows that, whatever the value of voltage V_{CTRL}, the sum of every DC current I₀ᵢ is constant.

The operation of amplifier 20 when voltage V_{CTRL} decreases is similar to the one described when voltage V_{CTRL} increases. It should only be noticed that a stage is automatically stopped when the current I₀ᵢ of the previous stage becomes smaller than P% of the bias current I_{bi}.

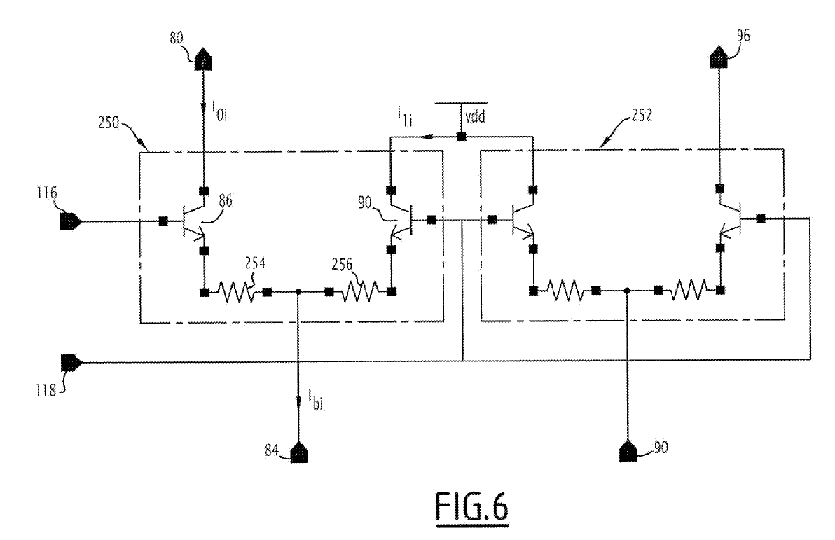

FIG. 6 shows another embodiment of a differential current divider having two current dividers 250 and 252 that can replace the differential current divider of any of stages 40-45. In FIG. 6, the elements of dividers 250 and 252 already described in FIG. 2 have the same references.

Dividers 250 and 252 are identical.

Divider 250 differs from divider 54 only by the fact that the emitters of transistors 86 and 90 are connected to point 84 through resistors 254 and 256, respectively. This reduces the sensitivity of amplifier 20 to noise within the signal outputted through outputs 116 and 118.

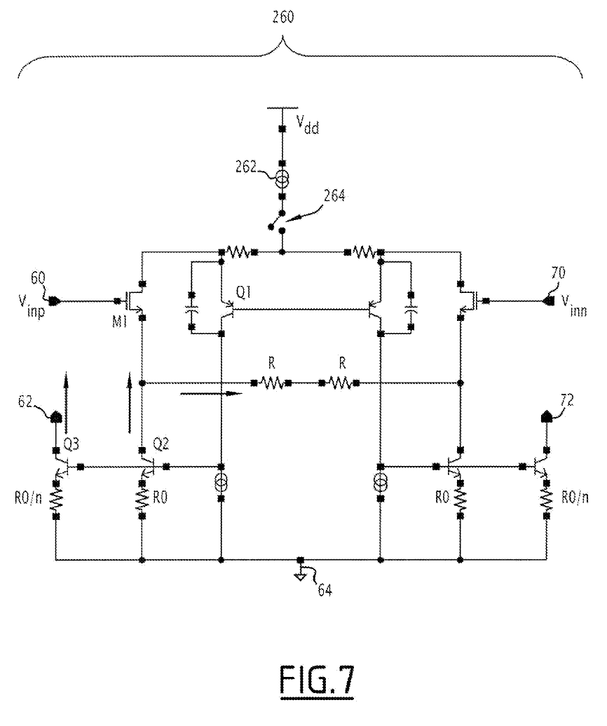

FIG. 7 shows a differential fixed gain transconductance amplifier 260 that can replace the two fixed gain transconductance amplifiers of any of stages 40-45.

In FIG. 7, the input and output points have the same references as those used in FIG. 2.

The schematic diagram of FIG. 7 is a well-known application diagram to those skilled in the art. Thus, only the elements of amplifier 260 that need to be modified to replace the fixed gain transconductance amplifier of FIG. 2 are described in detail.

Amplifier 260 has a controllable current source 262 to output a DC bias current.

A controllable switch 264 can be implemented at the output of source 262 to switch off the bias current. Switch 264 replaces switches 130 and 132. In fact, when switch 264 is switched to a non-conductive state, no bias current can flow through amplifier 260.

Current source 262 is controlled by voltage V_{SOUT} of loop 190. As a result, loop 190 can vary the intensity of the bias current Ibᵢ.

Many additional embodiments are possible. For example, any kind of fixed gain transconductance amplifiers can be used in amplifier 20.

The circuit of amplifier 20 can be adapted to non-differential inputs and outputs electrical signals.

If amplifier 20 needs to output an amplified periodic current, transformer stage 31 is omitted. Conversely, a current-to-voltage transformer stage can be added before input terminals 24 and 26 so as to receive an input AC current to be amplified and to output either an amplified current or an amplified voltage.

The gain-band product of loop 190 need not necessarily be greater than 3f₀.

Other ways of controlling the starting and stopping of amplifier stage can be implemented.

Amplifier 20 can be used in other circuits than an AGC circuit.

1. A monotonic variable gain amplifier which can be controlled to achieve a desired gain, the amplifier comprising:
at least one input terminal to receive a periodic electrical input signal to be amplified,
at least one output terminal to output a periodic current with an amplified amplitude according to the periodic electrical input signal, the outputted periodic current being combined with a DC voltage, wherein the monotonic variable gain amplifier comprises:
at least two amplifier stages connected in parallel between the input and output terminals, each amplifier stage including:
a fixed gain transconductance amplifier having at least one input point to receive the input signal, and a periodic current output through which a DC bias current flows controlled by the input signal,
a controllable current divider having a first and a second output point connected to the output terminal and to a voltage source respectively, and an input point connected to the fixed gain transconductance amplifier periodic current output, the current divider being controllable to vary the ratio of the amount of the DC bias current which is drawn from the first output point to the amount of the DC bias current which is drawn from the second output points, and
a control loop to keep the DC voltage combined with the outputted amplified periodic current at a constant level.

2. The amplifier according to claim 1, wherein:
at least one of the amplifier stages includes a controllable switch that can be switched from a conductive state in which the bias current can flow through the fixed gain transconductance amplifier to a non-conductive state in which the DC bias current cannot flows through the fixed gain transconductance amplifier, and
the monotonic variable gain amplifier comprises a control unit to automatically switch the controllable switch to the non-conductive state if the desired gain can be achieved using only the other amplifier stages with a bias current in each of the other stages lower than a predetermined threshold.

3. The amplifier according to claim 1, wherein the fixed gain transconductance amplifiers has a feedback loop to keep its gain constant.

4. The amplifier according to claim 1, wherein the fixed gain values of the transconductance amplifiers are chosen to form a geometric progression having a common ratio greater than two.

5. The amplifier according to claim 1, wherein:
the monotonic variable gain amplifier has two input terminals to receive a differential periodic electrical input signal and two output terminals to output a differential amplified periodic current, and
the product of the bandwidth at −3 dB of the control loop by the DC gain of the current control loop is greater than 3f₀, where f₀ is the frequency of the differential input signal.

6. The amplifier according to claim 1, wherein the current divider comprises:
a left transistor having a collector connected to the first output point and an emitter connected to the input point through a resistor, and
a right transistor having a collector connected to the voltage source and an emitter connected to the input point through another resistor of equal value.

7. An automatic gain control circuit comprising:
a monotonic variable gain amplifier having at least one input terminal to receive a periodic electrical signal and at least one output terminal to output an amplified periodic current, the monotonic variable gain amplifier being in conformity with any one of the preceding claims, and
a detector to tune the gain of the monotonic variable gain amplifier so as to keep the amplitude of the amplified periodic current signal constant even if the amplitude of the periodic electrical input signal varies.

8. A method of controlling a monotonic variable gain amplifier according to claim 2, wherein the switching of the controllable switch is automatically triggered as a function of the desired gain to be achieved.

9. The method according to claim 8, wherein the method comprises the step of switching the controllable switch of an amplifier stage to the conductive state at a time when the corresponding current divider is controlled not to draw any amount of the bias current of this stage from its first output pointy.

10. The method according to claim 8, wherein the method comprises the step of automatically switching the controllable switch of an amplifier stage to the conductive state when the amount of the bias current in another amplifier stage drawn from the first output point of this other amplifier stage reaches a predetermined percentage of the bias current, the predetermined percentage being at least higher than 80%.
